(19) United States
(12) Patent Application Publication
(10) Pub. No.: US 2010/0103624 A1
(43) Pub. Date: Apr. 29, 2010

(54) HEAT DISSIPATING DEVICE WITH TEMPERATURE DETECTING FUNCTION

(75) Inventors: MING-KE CHEN, Shenzhen City (CN); XIAO-ZHU CHEN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/277,254

(22) Filed: Nov. 24, 2008

(30) Foreign Application Priority Data
Oct. 24, 2008 (CN) 200810305126.4

(51) Int. Cl. H05K 7/20

(52) U.S. Cl. 361/710; 165/11.1

(57) ABSTRACT

A heat dissipating device with a temperature detecting function includes a heat sink module, a temperature detecting unit, a control unit, and a display unit. The heat sink module is configured for dissipating heat for a heat-generating electrical device. The temperature detecting unit is capable of sensing a temperature of the heat sink module, and converting an analog signal of the sensed temperature to a digital signal. The control unit transforms the digital signal to a display signal. The display unit receives the digital signal for displaying the sensed temperature.

### BACKGROUND

1. Technical Field

The present disclosure relates to heat dissipating devices, and particularly to a heat dissipating device with a temperature detecting function.

2. Description of the Related Art

Advances in microelectronic technology have resulted in electronic devices that can process signals and data at unprecedented high speeds. During operation of many contemporary electronic devices, such as central processing units (CPUs), large amounts of heat are produced, which must be dissipated quickly to prevent overheating of the electronic devices. Heat sinks are frequently used to dissipate heat from these electronic devices.

However, if the heat cannot be dissipated timely by the heat sinks, the temperature rises too high. If the temperature exceeds normal working temperature range of the electronic devices, service life of the electronic devices may reduce or even damage to the electronic devices.

### BRIEF DESCRIPTION OF THE DRAWINGS

FIG. 1 is an isometric, assembled view of an embodiment of a heat dissipating device with a display.

FIG. 2 is an exploded view of FIG. 1.

FIG. 3 is a block diagram of one embodiment of the heat dissipating device of FIG. 1.

FIG. 4 is one embodiment of a circuit diagram of FIG. 3.

### DETAILED DESCRIPTION

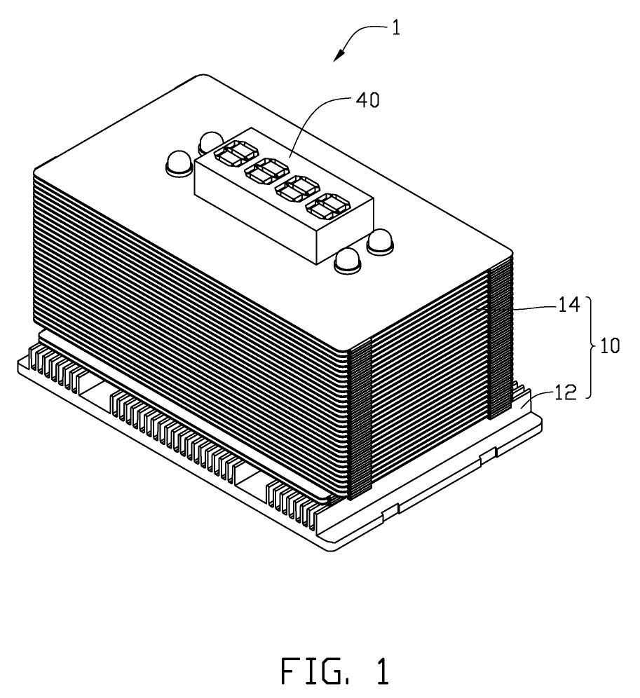

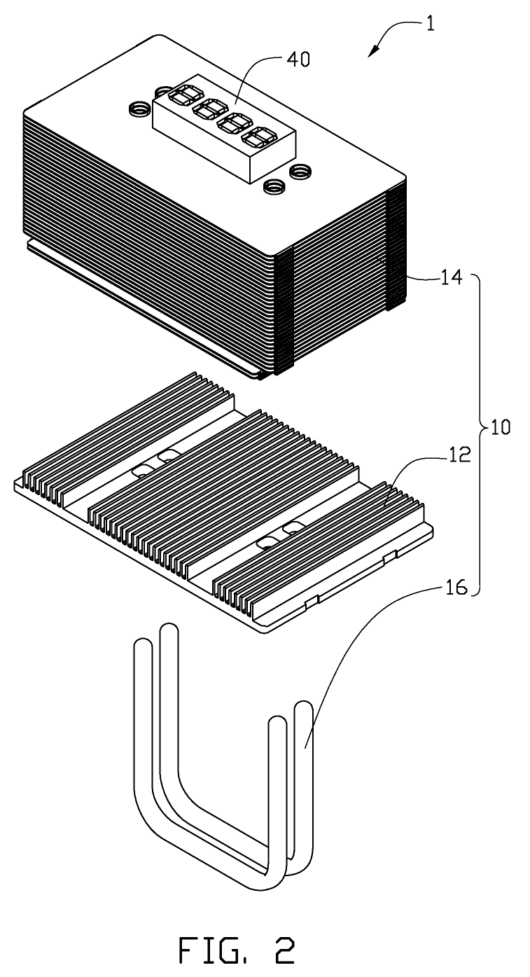

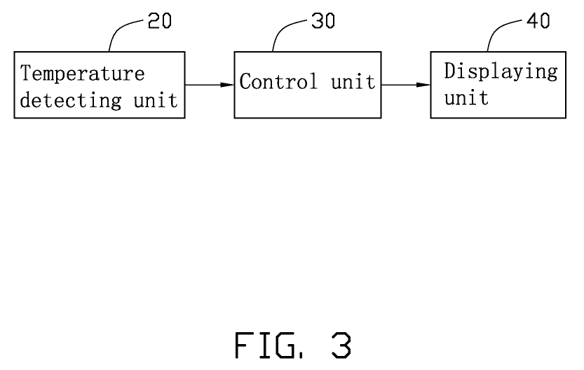

Referring to FIGS. 1 to 3, an embodiment of a heat dissipating device 1 with a temperature detecting function is configured to dissipate heat from a heat-generating electrical device (not shown), such as a central processing unit (CPU) of a computer. The heat dissipating device 1 includes a heat sink module 10 configured for dissipating heat generated by the heat-generating electrical device, a temperature detecting unit 20, a control unit 30, and a display unit 40. In one embodiment, the heat sink module 10 includes a master heat sink module 12 and an auxiliary heat sink module 14 connected to the master heat sink module 12 by two heat pipes 16.

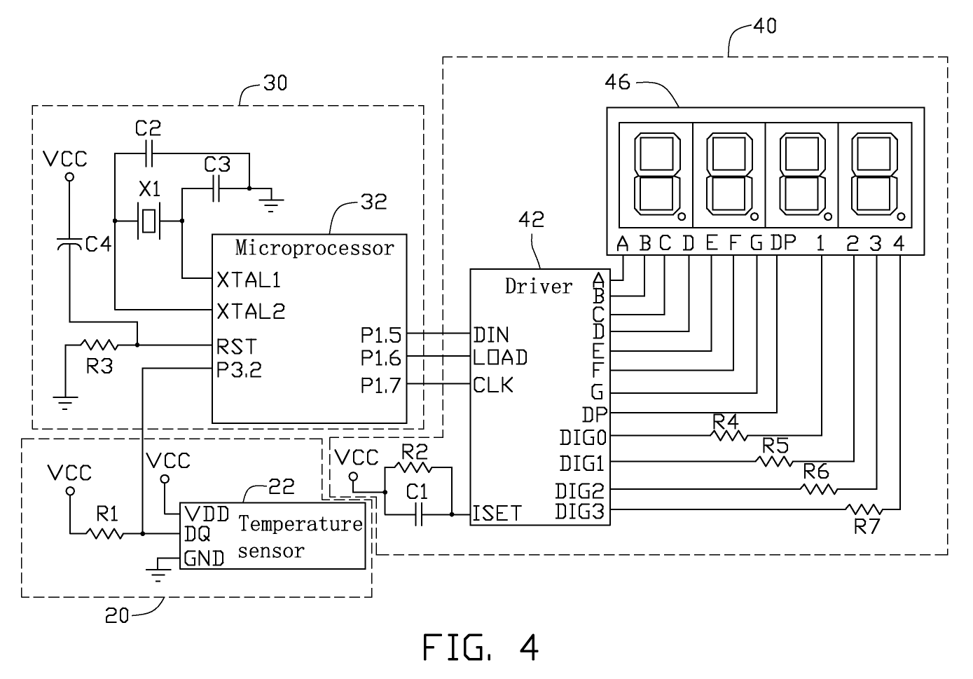

Referring to FIG. 4, the temperature detecting unit 20 includes a temperature sensor 22. In one embodiment, the temperature sensor 22 may be a single in-line, intellective sensor DS18B20, which is made by the DALLAS company. The temperature sensor 22 includes a power pin VDD, a data input output pin DQ, and a ground pin GND. The power pin VDD is connected to a power supply VCC, the data input output pin DQ is connected to the control unit 30, and connected to the power supply VCC via a resistor R1, and the ground pin GND is grounded.

The control unit 30 includes a microprocessor 32. In one embodiment, the microprocessor 32 is a single chip micyoco AT89C51, which is made by the ATMEI company. The microprocessor 32 includes an input pin P3.2, two clock signal pins XTAL1 and XTAL2, a reset pin RST, and three output pins P1.5-P1.7. The input pin P3.2 is connected to the data input output pin DQ of the temperature sensor 22. The clock signal pins XTAL1 and XTAL2 are connected to a clock circuit which includes a crystal oscillator X1, and two capacitors C2 and C3. The reset pin RST is connected to a reset circuit which includes a resistor R3, a capacitor C2, and the power supply VCC. The output pins P1.5-P1.7 are connected to the display unit 40. The clock circuit is used for providing working clock signals according to need. The reset circuit is used for resetting the microprocessor 32, when the microprocessor 32 is powered on.

The display unit 40 includes a driver 42 and a display 46. In one embodiment, the driver 42 may be a serially interfaced, 8-digit light-emitting diode (LED) display driver MAX7219, which is made by the MAXIM company. The driver 42 includes a data input pin DIN, a data load pin LOAD, a clock signal pin CLK, twelve output pins A-DP and DIG0-DIG3, and a pin ISET. The data input pin DIN is connected to the output pin P1.5 of the microprocessor 32. The data load pin LOAD is connected to the output pin P1.6 of the microprocessor 32. The clock signal pin CLK is connected to the output pin P1.7 of the microprocessor 32. The output pins A-DP and DIG0-DIG3 are connected to the display 46. The pin ISET is connected to the power supply VCC via a resistor R2. A capacitor C1 and the resistor R2 are connected in parallel between the pin ISET and the power supply VCC. In one embodiment, the display 46 may be a 4 digit 7 segment LED display including eight input pins A-DP connected to the corresponding output pins A-DP of the driver 42, and four input pins 1-4 the corresponding output pins DIG0-DIG3 of the driver 42.

In use, the heat sink module 10 dissipates heat from a heat-generating electrical device of a computer, for example. The temperature sensor 22 senses a current temperature of the heat sink module 10, and converts an analog signal of the sensed temperature to a digital signal, then transmits the digital signal serially to the input pin P3.2 of the microprocessor 32 via the data input output pin DQ. The microprocessor 32 transforms the serially transmitted digital signal to a display signal and transmits the display signal to the data input pin DIN of driver 42. The driver 42 drives the display 46 to display the temperature, for viewing by a user, sensed by the temperature sensor 22 according to the display signal received from the microprocessor 32. When the temperature exceeds normal working temperature range of the heat-generating electrical device, the user can turn off the computer, or provide additional cooling to lower the temperature of the heat-generating electrical device, in order to prevent damage from overheating and prolong the service life of the heat-generating electrical device.

In one embodiment, the display 46 is installed on the heat sink module 10. In other embodiments, the display 46 can be placed elsewhere, such as on a monitor of a computer, or on a front bezel for a computer enclosure, where user can check the temperature conveniently.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipating device with a temperature detecting function, comprising:
a heat sink module configured for dissipating heat from a heat-generating electrical device;
a temperature detecting unit capable of sensing a temperature of the heat sink module, and converting an analog signal of the sensed temperature into a digital signal, wherein the temperature detecting unit comprises a temperature sensor having a data input output pin configured for outputting the digital signal serially;
a control unit configured for transforming the serially transmitted digital signal to a display signal; and
a display unit receiving the display signal for displaying the sensed temperature.

2. The heat dissipating device of claim 1, wherein the data input output pin of the temperature detecting unit is connected to the control unit for transmitting the digital signal serially to the control unit, and connected to a power supply via a resistor.

3. The heat dissipating device of claim 2, wherein the temperature sensor is a single in-line, intellective sensor.

4. The heat dissipating device of claim 2, wherein the control unit comprises a microprocessor having an input pin connected to the data input output pin of the temperature sensor for receiving the digital signal, and an output pin connected to the display unit for transmitting the display signal to the display unit.

5. The heat dissipating device of claim 4, wherein the display unit comprises a driver and a display, the driver drives the display to display the temperature of the heat sink module according to the display signal.

6. The heat dissipating device of claim 5, wherein the driver comprises a data input pin connected to the microprocessor for receiving the display signal, and a plurality of output pins connected to the display for driving the display according to the display signal.

7. The heat dissipating device of claim 6, wherein the driver is a serially interfaced, 8-digit light-emitting diode (LED) display driver.

8. The heat dissipating device of claim 6, wherein the display a 4 digit 7 segment LED display.

9. The heat dissipating device of claim 1, wherein heat sink module comprises a master heat sink module and an auxiliary heat sink module installed on the master heat sink module by two heat pipes.
